(19) United States
(12) Patent Application Publication
(10) Pub. No.: US 2021/0288557 A1
(43) Pub. Date: Sep. 16, 2021

(54) MAGNETIC FIELD DETECTION APPARATUS, ROTATION DETECTION APPARATUS, AND ELECTRIC POWER STEERING SYSTEM

(71) Applicant: TDK CORPORATION, Tokyo (JP)

(72) Inventors: Yosuke KOMASAKI, Tokyo (JP); Naoki OHTA, Tokyo (JP)

(73) Assignee: TDK CORPORATION, Tokyo (JP)

(21) Appl. No.: 17/116,581

(22) Filed: Dec. 9, 2020

(30) Foreign Application Priority Data
Mar. 13, 2020 (JP) 2020-043715

(51) Int. Cl. H02K 11/215; H02K 7/116; B62D 5/04; G01D 5/16; G01B 7/30

(52) U.S. Cl. CPC H02K 11/215; H02K 7/116; G01B 7/30; G01D 5/16; B62D 5/0457

(57) ABSTRACT

A rotation detection apparatus includes a magnetic field generation source, a spin valve element, and a calculator. The magnetic field generation source is rotatable while generating a magnetic field, and has a temperature coefficient of residual magnetic flux density having an absolute value of 0.1%/° C. or less. The spin valve element includes a magnetic layer configured to generate a movement of a magnetic domain wall in accordance with a change in direction of the magnetic field associated with a rotation of the magnetic field generation source. The calculator is configured to detect a change in resistance of the spin valve element caused by the movement of the magnetic domain wall and to calculate the number of rotations or a rotation angle of the magnetic field generation source.

### CROSS REFERENCE TO RELATED APPLICATIONS

This application claims the benefit of Japanese Priority Patent Application No. 2020-043715 filed on Mar. 13, 2020, the entire contents of which are incorporated herein by reference.

### BACKGROUND

The technology relates to a magnetic field detection apparatus, a rotation detection apparatus, and an electric power steering system that each include a spin valve element.

A rotation counter has been proposed that counts the number of rotations of a rotating body by using a movement of a magnetic domain wall of a magnetic body. For example, reference is made to Japanese Unexamined Patent Application Publication (Published Japanese Translation of PCT Application) No. JP2019-502134. In such a rotation counter, a magnetic field generation source is rotated along with the rotating body, and a cumulative number of rotations of the rotating body is counted by detecting a state where the magnetic domain wall makes discontinuous movements due to changes in the direction of the magnetic field associated with the rotation.

### SUMMARY

A magnetic field detection apparatus according to one embodiment of the technology includes a magnetic field generation source and a spin valve element. The magnetic field generation source is configured to change its orientation while generating a magnetic field, and has a temperature coefficient of residual magnetic flux density having an absolute value of 0.1%/° C. or less. The spin valve element includes a magnetic layer configured to generate a movement of a magnetic domain wall in accordance with a change in direction of the magnetic field associated with a change in the orientation of the magnetic field generation source.

A rotation detection apparatus according to one embodiment of the technology includes a magnetic field generation source, a spin valve element, and a calculator. The magnetic field generation source is rotatable while generating a magnetic field, and has a temperature coefficient of residual magnetic flux density having an absolute value of 0.1%/° C. or less. The spin valve element includes a magnetic layer configured to generate a movement of a magnetic domain wall in accordance with a change in direction of the magnetic field associated with a rotation of the magnetic field generation source. The calculator is configured to detect a change in resistance of the spin valve element caused by the movement of the magnetic domain wall and to calculate the number of rotations or a rotation angle of the magnetic field generation source.

An electric power steering system according to one embodiment of the technology includes a motor configured to output a torque that assists a driver in steering, and a rotation detection apparatus configured to detect a rotation angle of the motor. The rotation detection apparatus includes a magnetic field generation source, a spin valve element, and a calculator. The magnetic field generation source is rotatable while generating a magnetic field, and has a temperature coefficient of residual magnetic flux density having an absolute value of 0.1%/° C. or less. The spin valve element includes a magnetic layer configured to generate a movement of a magnetic domain wall in accordance with a change in direction of the magnetic field associated with a rotation of the magnetic field generation source. The calculator is configured to detect a change in resistance of the spin valve element caused by the movement of the magnetic domain wall and to calculate the number of rotations or a rotation angle of the magnetic field generation source.

### BRIEF DESCRIPTION OF THE DRAWINGS

The accompanying drawings are included to provide a further understanding of the disclosure and are incorporated in and constitute a part of this specification. The drawings illustrate example embodiments and, together with the specification, serve to explain the principles of the technology.

FIG. 1 is a schematic perspective diagram illustrating an overall configuration example of a rotation detection apparatus according to one example embodiment of the technology.

FIG. 2 is a functional block diagram illustrating the overall configuration example of the rotation detection apparatus illustrated in FIG. 1.

FIG. 3A is a planar diagram illustrating a configuration example of a rotation sensor in the rotation detection apparatus illustrated in FIG. 1.

FIG. 3B is an exploded perspective diagram schematically illustrating a configuration example of a spin valve pattern.

FIG. 4A is an explanatory diagram illustrating a first state of the rotation sensor illustrated in FIG. 3A in detection operation.

FIG. 4B is an explanatory diagram illustrating a second state of the rotation sensor illustrated in FIG. 3A in detection operation.

FIG. 4C is an explanatory diagram illustrating a third state of the rotation sensor illustrated in FIG. 3A in detection operation.

FIG. 4D is an explanatory diagram illustrating a fourth state of the rotation sensor illustrated in FIG. 3A in detection operation.

FIG. 4E is an explanatory diagram illustrating a fifth state of the rotation sensor illustrated in FIG. 3A in detection operation.

FIG. 4F is an explanatory diagram illustrating a sixth state of the rotation sensor illustrated in FIG. 3A in detection operation.

FIG. 4G is an explanatory diagram illustrating a seventh state of the rotation sensor illustrated in FIG. 3A in detection operation.

FIG. 4H is an explanatory diagram illustrating an eighth state of the rotation sensor illustrated in FIG. 3A in detection operation.

FIG. 4I is an explanatory diagram illustrating a ninth state of the rotation sensor illustrated in FIG. 3A in detection operation.

FIG. 4J is an explanatory diagram illustrating a tenth state of the rotation sensor illustrated in FIG. 3A in detection operation.

FIG. 4K is an explanatory diagram illustrating an eleventh state of the rotation sensor illustrated in FIG. 3A in detection operation.

FIG. 4L is an explanatory diagram illustrating a twelfth state of the rotation sensor illustrated in FIG. 3A in detection operation.

FIG. 4M is an explanatory diagram illustrating a thirteenth state of the rotation sensor illustrated in FIG. 3A in detection operation.

FIG. 5 is a schematic diagram illustrating components of a vehicle incorporating the rotation detection apparatus illustrated in FIG. 1.

FIG. 6 is a schematic plan view of a planar shape of a spin valve pattern according to a modification example.

### DETAILED DESCRIPTION

Stable operation performance is demanded of a rotation counter (a rotation detection apparatus) that counts the number of rotations of a rotating body by using a movement of a magnetic domain wall of a magnetic body.

It is desirable to provide a magnetic field detection apparatus, a rotation detection apparatus, and an electric power steering system including the rotation detection apparatus that each exhibit stable operation performance over a wider temperature range.

Existing rotation detection apparatuses are able to perform intended operations with stability over a limited range of magnetic field intensities. Depending on the intended use, it is thus sometimes difficult for such apparatuses to fully meet the performance expectations. Furthermore, a magnet used as a magnetic field generation source in a rotation detection apparatus typically has a temperature coefficient of residual magnetic flux density, and therefore the intensity of the magnetic field generated by the magnet varies depending on the ambient temperature. Given these circumstances, an embodiment of the technology provides a magnetic field detection apparatus, a rotation detection apparatus, and an electric power steering system that each exhibit stable operation performance over a wider temperature range.

In the following, some example embodiments and modification examples of the technology are described in detail with reference to the accompanying drawings. Note that the following description is directed to illustrative examples of the disclosure and not to be construed as limiting the technology. Factors including, without limitation, numerical values, shapes, materials, components, positions of the components, and how the components are coupled to each other are illustrative only and not to be construed as limiting the technology. Further, elements in the following example embodiments which are not recited in a most-generic independent claim of the disclosure are optional and may be provided on an as-needed basis. The drawings are schematic and are not intended to be drawn to scale. Like elements are denoted with the same reference numerals to avoid redundant descriptions. Note that the description is given in the following order.
1. Example Embodiment

An example of a rotation detection apparatus including a spin valve element with a spirally winding linear pattern
2. Application Example

An example of a power steering system
3. Modification Example

### 1. EXAMPLE EMBODIMENT

### [Configuration of Rotation Detection Apparatus 100]

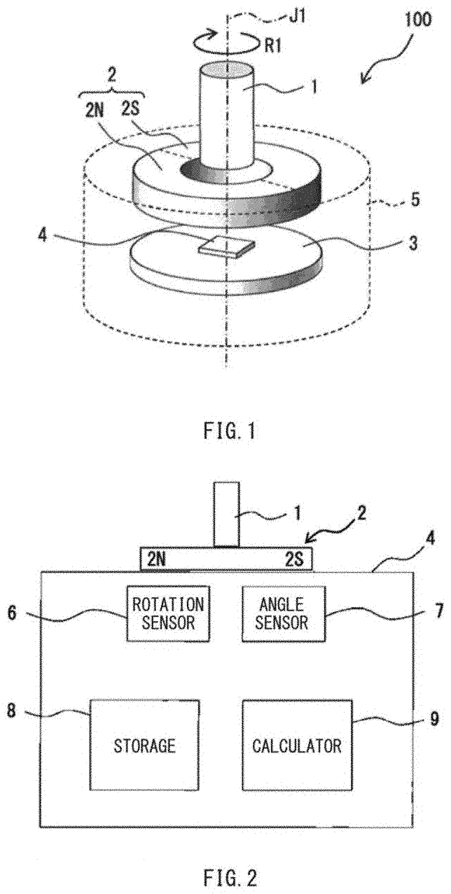

First, a configuration of a rotation detection apparatus 100 according to one example embodiment of the technology will be described with reference to FIGS. 1 to 3.

FIG. 1 is a schematic perspective diagram illustrating an overall configuration example of the rotation detection apparatus 100. As illustrated in FIG. 1, the rotation detection apparatus 100 may include, for example, a shaft 1 shaped like a rod, a magnet 2 shaped like a ring, a substrate 3 shaped like a circular plate, and a chip 4 mounted on the substrate 3. The rotation detection apparatus 100 may further include a housing 5 to accommodate the magnet 2, the substrate 3, and the chip 4. The shaft 1 may be joined to the magnet 2. The shaft 1 and the magnet 2 as an integral whole may rotate in a rotation direction R1 with respect to the housing 5 around an axis of rotation J1. The substrate 3 and the chip 4 may be disposed near the magnet 2 and held by the housing 5 so as not to rotate. In FIG. 1, the housing 5 is indicated by broken lines to make the interior structure of the rotation detection apparatus 100 visible.

It is to be noted that the rotation detection apparatus 100 may correspond to a specific but non-limiting example of a “rotation detection apparatus” according to one embodiment of the technology, and may also correspond to a specific but non-limiting example of a “magnetic field detection apparatus” according to one embodiment of the technology.

The magnet 2 may correspond to a specific but non-limiting example of a “magnetic field generation source” according to one embodiment of the technology. The magnetic field generation source may generate a magnetic field Hm, which will be described later, to be exerted on the chip 4. The magnet 2 may be, for example, a permanent magnet including an N pole 2N and an S pole 2S. The magnet 2 is configured to change its orientation with respect to the chip 4 by rotating around the axis of rotation J1, while generating the magnetic field Hm. In one example embodiment, the magnet 2 has a temperature coefficient of residual magnetic flux density having an absolute value of 0.1%/° C. or less. One reason for this is that this serves to suppress a change in magnetic field intensity associated with a change in the ambient temperature to a small level. In some embodiments, the magnet 2 may be an AlNiCo magnet including aluminum (Al), nickel (Ni), and cobalt (Co) as constituent materials. The AlNiCo magnet has a temperature coefficient of residual magnetic flux density of about −0.02%/° C. In other some embodiments, the magnet 2 may be a samarium cobalt magnet including samarium (Sm) and cobalt (Co) as constituent materials. One reason for this is that the samarium cobalt magnet is able to generate a magnetic field Hm higher in intensity than a magnetic field Hm that the AlNiCo magnet generates. The samarium cobalt magnet has a temperature coefficient of residual magnetic flux density of about −0.03%/° C. Although FIG. 1 illustrates the magnet 2 in the shape like a ring that expands along a plane orthogonal to the axis of rotation J1, the present example embodiment is not limited thereto.

FIG. 2 is a functional block diagram illustrating an overall configuration example of the rotation detection apparatus 100. As illustrated in FIG. 2, the chip 4 may include a rotation sensor 6, an angle sensor 7, a storage 8, and a calculator 9. The rotation sensor 6 may be a device that detects the number of rotations of the magnet 2 rotating with respect to the chip 4. The angle sensor 7 may be a device that detects a rotation angle of the magnet 2 rotating with respect to the chip 4. The storage 8 may store any of, for example, measured value information related to the number of rotations of the magnet 2 detected by the rotation sensor 6, measured value information related to the rotation angle of the magnet 2 detected by the angle sensor 7, and information related to various programs. The calculator 9 may be, for example, a central processing unit (CPU) serving as an operational processing unit. The calculator 9 may calculate the number of rotations of the magnet 2 and the rotation angle of the magnet 2 on the basis of the measured value information related to the number of rotation of the magnet 2 supplied from the rotation sensor 6 and the measured value information related to the rotation angle of the magnet 2 supplied from the angle sensor 7, for example. The storage 8 and the calculator 9 may constitute a circuit including, for example, the CPU, a read-only memory (ROM), and a random access memory (RAM). The ROM is a storage device that may store programs, operational parameters, etc. to be used by the CPU. The RAM is a storage device that may temporarily store parameters, etc. to be changed as appropriate during execution of processing by the CPU.

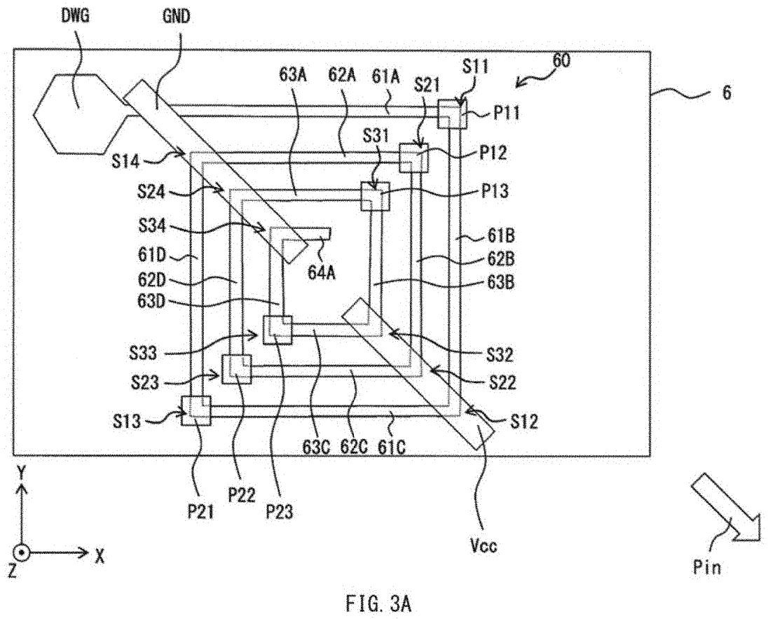

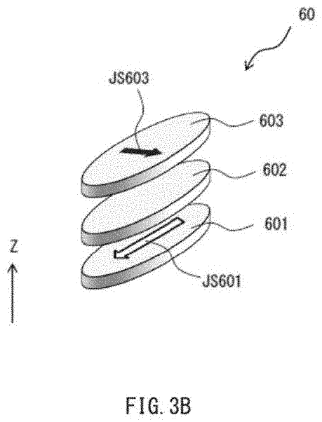

FIG. 3A is a planar diagram schematically illustrating a configuration example of the rotation sensor 6 in the rotation detection apparatus 100. As illustrated in FIG. 3A, the rotation sensor 6 may include a spin valve (SV) pattern 60 that winds spirally in an XY plane. In FIG. 3A, a Z-axis is parallel to the axis of rotation J1, and the XY plane is orthogonal to the Z-axis (the axis of rotation J1). FIG. 3B is an exploded perspective diagram schematically illustrating a configuration example of the SV pattern 60. The SV pattern 60 may be, for example, a magnetoresistive effect element having a spin valve structure including a magnetization free layer 601, a nonmagnetic intermediate layer 602, and a magnetization pinned layer 603 that are stacked in a Z-axis direction. The magnetization free layer 601 has a magnetization JS601 that changes its direction in accordance with an external magnetic field. The magnetization pinned layer 603 has a magnetization JS603 pinned in a certain direction. The SV pattern 60 changes in resistance in accordance with a relative angle between the direction of the magnetization JS601 of the magnetization free layer 601 and the direction of the magnetization JS603 of the magnetization pinned layer 603. The SV pattern 60 may be a tunneling magnetoresistive effect (TMR) (magnetic tunnel junction) element or a giant magnetoresistive effect (GMR) element. The magnetization free layer 601 is configured to generate a movement of a magnetic domain wall in accordance with a change in the direction of the magnetic field Hm associated with a change in the orientation of the magnet 2, that is, a rotation movement of the magnet 2 around the axis of rotation J1. It is to be noted that the SV pattern 60 may have a configuration in which only the magnetization free layer 601 has a spiral shape in a plan view as illustrated in FIG. 3A whereas the nonmagnetic intermediate layer 602 and the magnetization pinned layer 603 each have a shape corresponding to only a portion of the magnetization free layer 601, such as a rectangular shape, in a plan view. In other words, in the SV pattern 60, the magnetization free layer 601, the nonmagnetic intermediate layer 602, and the magnetization pinned layer 603 may be identical to each other in planar shape, or at least one of the magnetization free layer 601, the nonmagnetic intermediate layer 602, or the magnetization pinned layer 603 may be different in planar shape. In either case, in the present example embodiment, the planar shape of the magnetization free layer 601 may be identical to that of the SV pattern 60 illustrated in FIG. 3A.

The magnetization free layer 601 may correspond to a specific but non-limiting example of a “magnetic layer” according to one embodiment of the technology.

The magnetization free layer 601 in the SV pattern 60 may have its magnetization JS601 along the XY plane. The SV pattern 60 may configure a linear pattern that winds spirally along the XY plane. As used herein, the term “linear” refers to a shape represented by a line or lines of any shape that are not limited to straight lines. The linear pattern configured by the SV pattern 60 may include straight-line parts 61A to 61D, 62A to 62D, 63A to 63D, and 64A that each extend straight along the XY plane, and bend parts S11 to S14, S21 to S24, and S31 to S34 that each couple corresponding two of the straight-line parts 61A to 61D, 62A to 62D, 63A to 63D, and 64A to each other.

In a more specific but non-limiting example, the straight-line part 61A and the straight-line part 61B may extend in an X-axis direction and a Y-axis direction, respectively, with a first end of the straight-line part 61A and a second end of the straight-line part 61B being coupled to each other at the bend part S11. A second end of the straight-line part 61A opposite to the bend part S11 may be coupled to a magnetic domain wall generator DWG. The magnetic domain wall generator DWG may have an SV structure the same as that of the SV pattern 60, and may generate a magnetic domain wall at a boundary between the magnetic domain wall generator DWG and the straight-line part 61A every time the direction of the magnetic field Hm generated by the magnet 2 rotates by 180°, for example. Note that the magnetic domain wall generator DWG may have an SV structure different from that of the SV pattern 60, or may be a magnetic layer without an SV structure. A straight-line part 61C may extend in the X-axis direction. A first end of the straight-line part 61B and a second end of the straight-line part 61C may be coupled to each other at the bend part S12. The straight-line part 61D may extend in the Y-axis direction. A first end of the straight-line part 61C and a second end of the straight-line part 61D may be coupled to each other at the bend part S13. The straight-line part 62A may extend in the X-axis direction. A first end of the straight-line part 61D and a second end of the straight-line part 62A may be coupled to each other at the bend part S14. The straight-line part 62B may extend in the Y-axis direction. A first end of the straight-line part 62A and a second end of the straight-line part 62B may be coupled to each other at the bend part S21. The straight-line part 62C may extend in the X-axis direction. A first end of the straight-line part 62B and a second end of the straight-line part 62C may be coupled to each other at the bend part S22. The straight-line part 62D may extend in the Y-axis direction. A first end of the straight-line part 62C and a second end of the straight-line part 62D may be coupled to each other at the bend part S23. The straight-line part 63A may extend in the X-axis direction. A first end of the straight-line part 62D and a second end of the straight-line part 63A may be coupled to each other at the bend part S24. The straight-line part 63B may extend in the Y-axis direction. A first end of the straight-line part 63A and a second end of the straight-line part 63B may be coupled to each other at the bend part S31. The straight-line part 63C may extend in the X-axis direction. A first end of the straight-line part 63B and a second end of the straight-line part 63C may be coupled to each other at the bend part S32. The straight-line part 63D may extend in the Y-axis direction. A first end of the straight-line part 63C and a second end of the straight-line part 63D may be coupled to each other at the bend part S33. The straight-line part 64A may extend in the X-axis direction. A first end of the straight-line part 63D and a second end of the straight-line part 64A may be coupled to each other at the bend part S34. A first end of the straight-line part 64A may be open. The bend parts S11 to S14, S21 to S24, and S31 to S34 may serve to temporarily prevent a magnetic domain wall generated by the magnetic domain wall generator DWG from moving inside the magnetization free layer 601, thus trapping the magnetic domain wall thereat.

A pad P11 may be provided on the bend part S11. A pad P12 may be provided on the bend part S21. A pad P13 may be provided on the bend part S31. A pad P21 may be provided on the bend part S13. A pad P22 may be provided on the bend part S23. A pad P23 may be provided on the bend part S33. A power supply terminal Vcc may be coupled to the bend parts S12, S22, and S32 in common. A ground terminal GND may be coupled to the bend parts S14, S24, and S34 in common. Such a configuration may allow the rotation sensor 6 to feed a sense current through each of the straight-line parts 61A to 61D, 62A to 62D, and 63A to 63D, and to thereby detect an electrical resistance dependent on the position of the magnetic domain wall in the magnetization free layer 601 of the SV pattern 60.

### [Operation of Rotation Sensor 6]

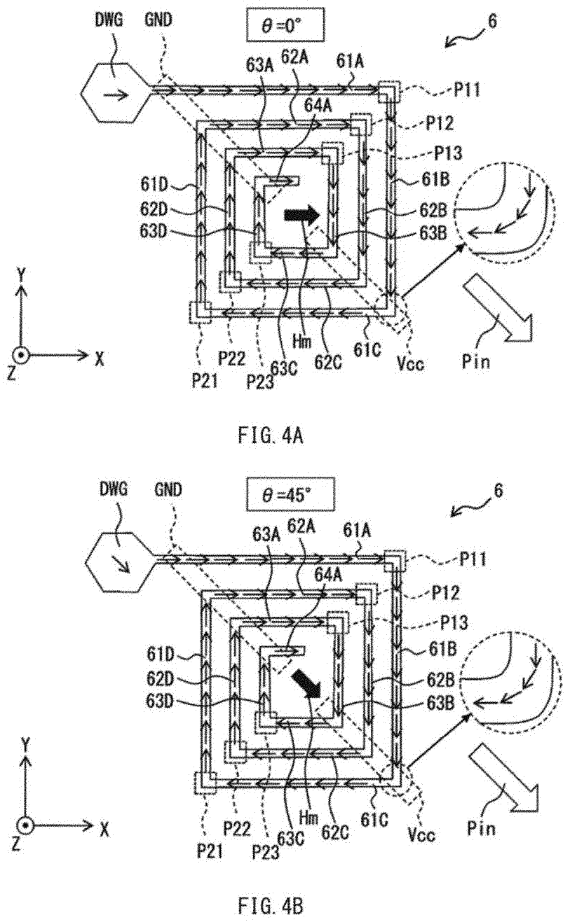

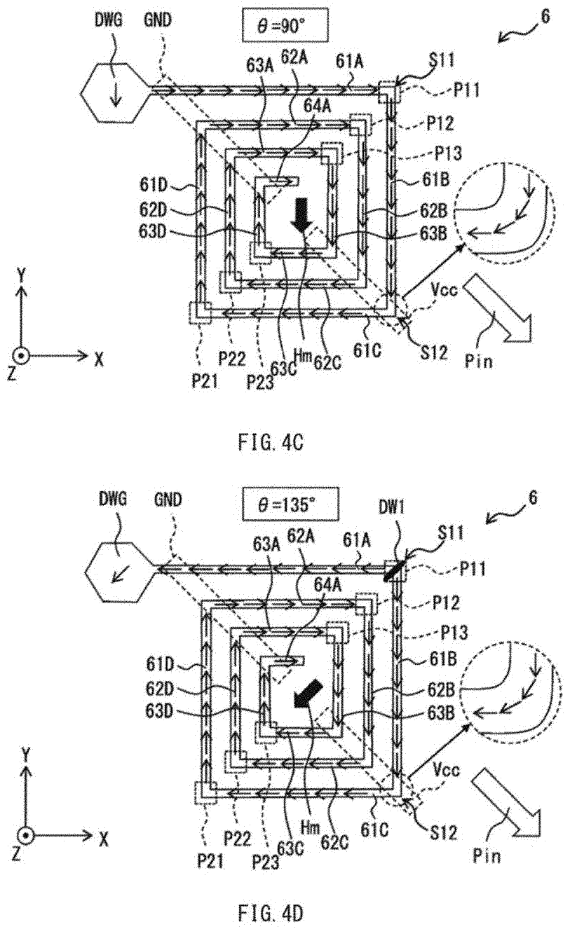

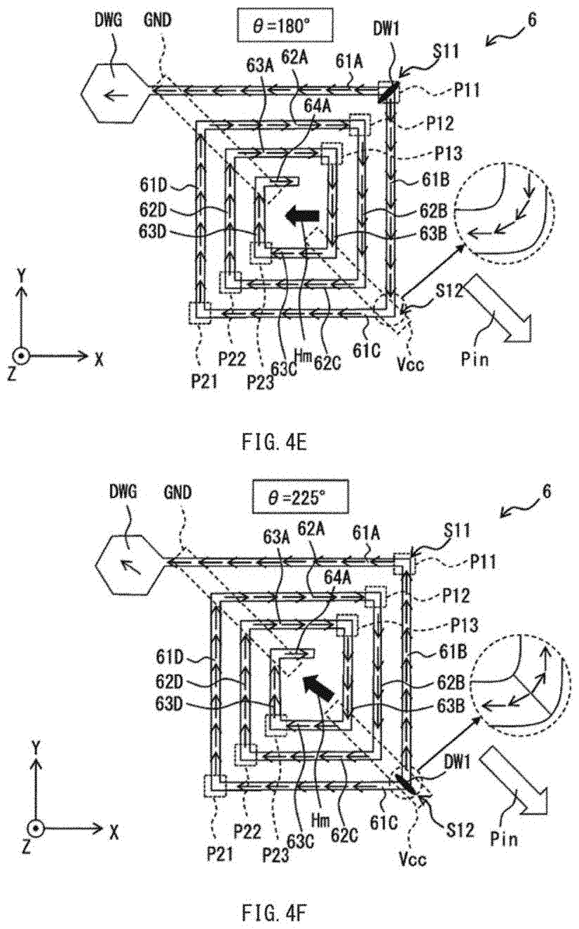

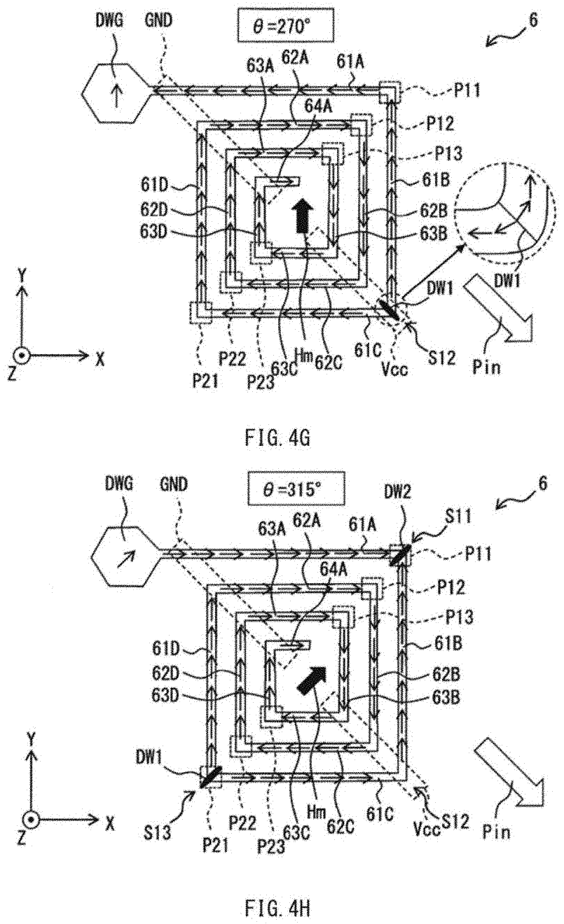

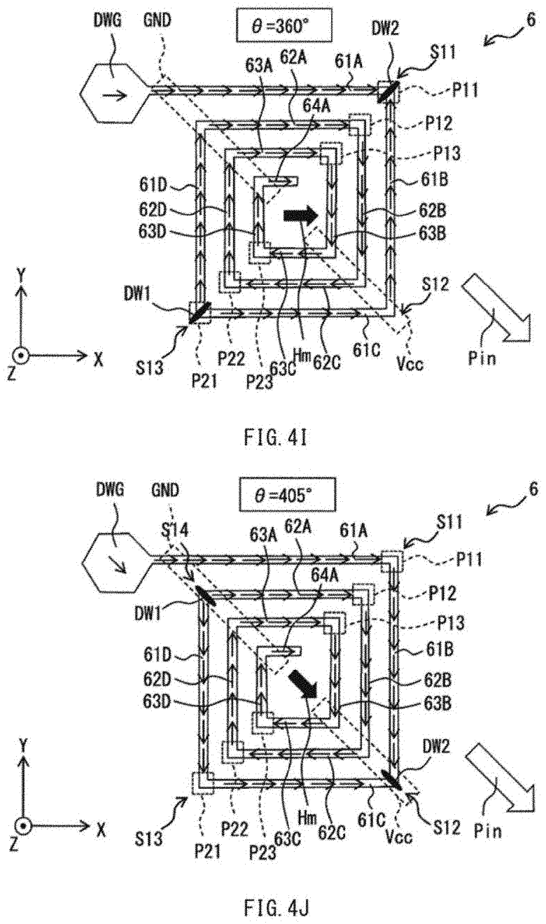

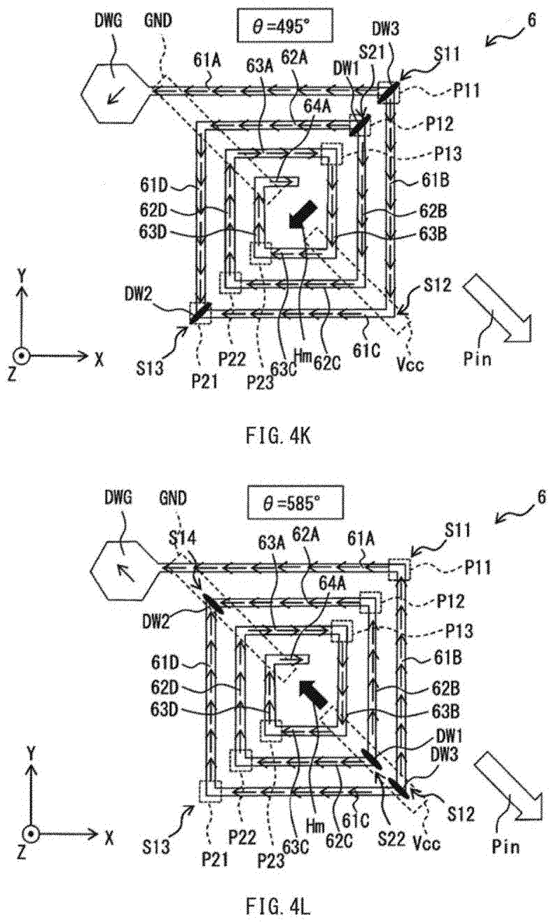

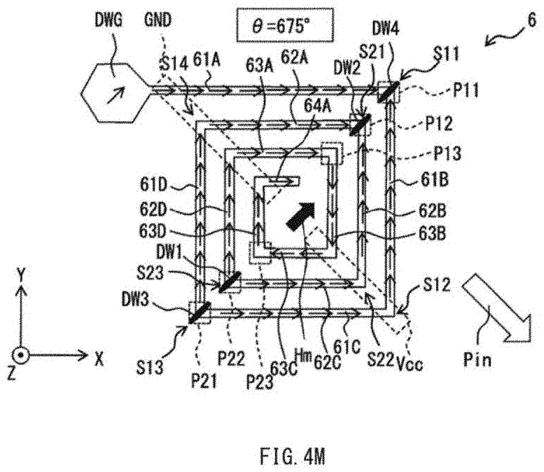

Next, with reference to FIGS. 4A to 4M, a description will be given of operation of the rotation sensor 6 associated with rotation of the magnet 2. In each of FIGS. 4A to 4M, a solid black arrow at the center of the spirally winding SV pattern 60 indicates the direction of the magnetic field Hm generated by the magnet 2. FIG. 4A illustrates a state at a rotation angle θ of 0°, that is, a reference position at which the magnet 2 starts rotation. The direction of the magnetic field Hm when the rotation angle θ is 0° may be set to a +X direction. In such a case, at this point, magnetization directions of the magnetization free layer 601 at the straight-line parts 61A to 61D, 62A to 62D, 63A to 63D, and 64A are as indicated by thin arrows in FIG. 4A. That is, the magnetization JS601 of the magnetization free layer 601 is in the +X direction at the straight-line parts 61A, 62A, 63A, and 64A, in a −Y direction at the straight-line parts 61B, 62B, and 63B, in a −X direction at the straight-line parts 61C, 62C, and 63C, and in a +Y direction at the straight-line parts 61D, 62D, and 63D. When in this state, the magnetization free layer 601 has no magnetic domain wall at any of the bend parts S11 to S14, S21 to S24, and S31 to S34.

FIG. 4B illustrates a state at a rotation angle θ of 45°, that is, a state where the magnet 2 has rotated 45° clockwise from the reference position, i.e. the state at a rotation angle θ of 0°. At this point, a magnetization direction at the magnetic domain wall generator DWG is in a 45° inclined state relative to the reference position, as with the direction of the magnetic field Hm. However, the magnetization directions of the magnetization free layer 601 at the straight-line parts 61A to 61D, 62A to 62D, 63A to 63D, and 64A are unchanged from those in FIG. 4A. When in this state, the magnetization free layer 601 has no magnetic domain wall at any of the bend parts S11 to S14, S21 to S24, and S31 to S34, either.

FIG. 4C illustrates a state at a rotation angle θ of 90°, that is, a state where the magnet 2 has rotated 45° clockwise from the state at a rotation angle θ of 45°. At this point, the magnetization direction at the magnetic domain wall generator DWG is in a 90° inclined state relative to the reference position, as with the direction of the magnetic field Hm. However, the magnetization directions of the magnetization free layer 601 at the straight-line parts 61A to 61D, 62A to 62D, 63A to 63D, and 64A are unchanged from those in FIG. 4A. When in this state, the magnetization free layer 601 has no magnetic domain wall at any of the bend parts S11 to S14, S21 to S24, and S31 to S34, either.

FIG. 4D illustrates a state at a rotation angle θ of 135°, that is, a state where the magnet 2 has rotated 45° clockwise from the state at a rotation angle θ of 90°. At this point, the magnetization direction at the magnetic domain wall generator DWG is in a 135° inclined state relative to the reference position, as with the direction of the magnetic field Hm. As a result, a magnetic domain wall DW1 generated at the magnetic domain wall generator DWG moves to the bend part S11 through the straight-line part 61A and is trapped at the bend part S11. Consequently, the magnetization direction of the magnetization free layer 601 at the straight-line part 61A is reversed from the +X direction to the −X direction. However, the magnetization directions of the magnetization free layer 601 at the straight-line parts 61B to 61D, 62A to 62D, 63A to 63D, and 64A are unchanged from those in FIG. 4A.

FIG. 4E illustrates a state at a rotation angle θ of 180°, that is, a state where the magnet 2 has rotated 45° clockwise from the state at a rotation angle θ of 135°. At this point, the magnetization direction at the magnetic domain wall generator DWG is in a 180° reversed state relative to the reference position, as with the direction of the magnetic field Hm. However, the magnetization direction of the magnetization free layer 601 at the straight-line part 61A remains in the −X direction, and the magnetic domain wall DW1 remains trapped at the bend part S11. The magnetization directions of the magnetization free layer 601 at the straight-line parts 61B to 61D, 62A to 62D, 63A to 63D, and 64A are unchanged from those in FIG. 4D.

FIG. 4F illustrates a state at a rotation angle θ of 225°, that is, a state where the magnet 2 has rotated 45° clockwise from the state at a rotation angle θ of 180°. At this point, the magnetization direction at the magnetic domain wall generator DWG is in a 225° rotated state relative to the reference position, as with the direction of the magnetic field Hm. As a result, the magnetic domain wall DW1 moves from the bend part S11 to the bend part S12 through the straight-line part 61B, and is trapped at the bend part S12. Consequently, the magnetization direction of the magnetization free layer 601 at the straight-line part 61B is reversed from the −Y direction to the +Y direction. However, the magnetization directions of the magnetization free layer 601 at the straight-line parts 61A, 61C, 61D, 62A to 62D, 63A to 63D, and 64A are unchanged from those in FIG. 4E.

FIG. 4G illustrates a state at a rotation angle θ of 270°, that is, a state where the magnet 2 has rotated 45° clockwise from the state at a rotation angle θ of 225°. At this point, the magnetization direction at the magnetic domain wall generator DWG is in a 270° rotated state relative to the reference position, as with the direction of the magnetic field Hm. However, the magnetization directions of the magnetization free layer 601 at the straight-line parts 61A to 61D, 62A to 62D, 63A to 63D, and 64A are unchanged from those in FIG. 4F, and the magnetic domain wall DW1 remains trapped at the bend part S12.

FIG. 4H illustrates a state at a rotation angle θ of 315°, that is, a state where the magnet 2 has rotated 45° clockwise from the state at a rotation angle θ of 270°. At this point, the magnetization direction at the magnetic domain wall generator DWG is in a 315° rotated state relative to the reference position, as with the direction of the magnetic field Hm. As a result, the magnetic domain wall DW1 moves from the bend part S12 to the bend part S13 through the straight-line part 61C, and is trapped at the bend part S13. Consequently, the magnetization direction of the magnetization free layer 601 at the straight-line part 61C is reversed from the −X direction to the +X direction. Further, a magnetic domain wall DW2 newly generated at the magnetic domain wall generator DWG moves to the bend part S11 through the straight-line part 61A, and is trapped at the bend part S11. Consequently, the magnetization direction of the magnetization free layer 601 at the straight-line part 61A is reversed from the −X direction to the +X direction, and the magnetization direction of the magnetization free layer 601 at the straight-line part 61B is reversed from the −Y direction to the +Y direction. However, the magnetization directions of the magnetization free layer 601 at the straight-line parts 61D, 62A to 62D, 63A to 63D, and 64A are unchanged from those in FIG. 4G.

FIG. 4I illustrates a state at a rotation angle θ of 360°, that is, a state where the magnet 2 has rotated 45° clockwise from the state at a rotation angle θ of 315°. At this point, the magnetization direction at the magnetic domain wall generator DWG is in a 360° rotated state relative to the reference position, as with the direction of the magnetic field Hm. However, the magnetization directions of the magnetization free layer 601 at the straight-line parts 61A to 61D, 62A to 62D, 63A to 63D, and 64A are unchanged from those in FIG. 4H. The magnetic domain wall DW1 remains trapped at the bend part S13, and the magnetic domain wall DW2 remains trapped at the bend part S11.

FIG. 4J illustrates a state at a rotation angle θ of 405°, that is, a state where the magnet 2 has rotated 45° clockwise from the state at a rotation angle θ of 360°. At this point, the magnetization direction at the magnetic domain wall generator DWG is in a 405° rotated state relative to the reference position, as with the direction of the magnetic field Hm. As a result, the magnetic domain wall DW1 moves from the bend part S13 to the bend part S14 through the straight-line part 61D, and is trapped at the bend part S14. Consequently, the magnetization direction of the magnetization free layer 601 at the straight-line part 61D is reversed from the +Y direction to the −Y direction. Further, the magnetic domain wall DW2 moves from the bend part S11 to the bend part S12 through the straight-line part 61B, and is trapped at the bend part S12. Consequently, the magnetization direction of the magnetization free layer 601 at the straight-line part 61B is reversed from the +Y direction to −Y direction. However, the magnetization directions of the magnetization free layer 601 at the straight-line parts 61A, 61C, 62A to 62D, 63A to 63D, and 64A are unchanged from those in FIG. 4I.

FIG. 4K illustrates a state at a rotation angle θ of 495°, that is, a state where the magnet 2 has rotated 90° clockwise from the state at a rotation angle θ of 405°. At this point, the magnetization direction at the magnetic domain wall generator DWG is in a 495° rotated state relative to the reference position, as with the direction of the magnetic field Hm. As a result, the magnetic domain wall DW1 moves from the bend part S14 to the bend part S21 through the straight-line part 62A, and is trapped at the bend part S21. Consequently, the magnetization direction of the magnetization free layer 601 at the straight-line part 62A is reversed from the +X direction to the −X direction. Further, the magnetic domain wall DW2 moves from the bend part S12 to the bend part S13 through the straight-line part 61C, and is trapped at the bend part S13. Consequently, the magnetization direction of the magnetization free layer 601 at the straight-line part 61C is reversed from the +X direction to the −X direction. Further, a magnetic domain wall DW3 newly generated at the magnetic domain wall generator DWG moves to the bend part S11 through the straight-line part 61A, and is trapped at the bend part S11. Consequently, the magnetization direction of the magnetization free layer 601 at the straight-line part 61A is reversed from the +X direction to the −X direction. However, the magnetization directions of the magnetization free layer 601 at the straight-line parts 61B, 61D, 62B to 62D, 63A to 63D, and 64A are unchanged from those in FIG. 4J.

FIG. 4L illustrates a state at a rotation angle θ of 585°, that is, a state where the magnet 2 has rotated 90° clockwise from the state at a rotation angle θ of 495°. At this point, the magnetization direction at the magnetic domain wall generator DWG is in a 585° rotated state relative to the reference position, as with the direction of the magnetic field Hm. As a result, the magnetic domain wall DW1 moves from the bend part S21 to the bend part S22 through the straight-line part 62B, and is trapped at the bend part S22. As a result, the magnetization direction of the magnetization free layer 601 at the straight-line part 62B is reversed from the −Y direction to the +Y direction. Further, the magnetic domain wall DW2 moves from the bend part S13 to the bend part S14 through the straight-line part 61D, and is trapped at the bend part S14. Consequently, the magnetization direction of the magnetization free layer 601 at the straight-line part 61D is reversed from the −Y direction to the +Y direction. Further, the magnetic domain wall DW3 moves from the bend part S11 to the bend part S12 through the straight-line part 61B, and is trapped at the bend part S12. Consequently, the magnetization direction of the magnetization free layer 601 at the straight-line part 61B is reversed from the −Y direction to the +Y direction. However, the magnetization directions of the magnetization free layer 601 at the straight-line parts 61A, 61C, 62A, 62C, 62D, 63A to 63D, and 64A are unchanged from those in FIG. 4K.

FIG. 4M illustrates a state at a rotation angle θ of 675°, that is, a state where the magnet 2 has rotated 90° clockwise from the state at a rotation angle θ of 585°. At this point, the magnetization direction at the magnetic domain wall generator DWG is in a 675° rotated state relative to the reference position, as with the direction of the magnetic field Hm. As a result, the magnetic domain wall DW1 moves from the bend part S22 to the bend part S23 through the straight-line part 62C, and is trapped at the bend part S23. Consequently, the magnetization direction of the magnetization free layer 601 at the straight-line part 62C is reversed from the −X direction to the +X direction. Further, the magnetic domain wall DW2 moves from the bend part S14 to the bend part S21 through the straight-line part 62A, and is trapped at the bend part S21. Consequently, the magnetization direction of the magnetization free layer 601 at the straight-line part 62A is reversed from the −X direction to the +X direction. Further, the magnetic domain wall DW3 moves from the bend part S12 to the bend part S13 through the straight-line part 61C, and is trapped at the bend part S13. Consequently, the magnetization direction of the magnetization free layer 601 at the straight-line part 61C is reversed from the −X direction to the +X direction. Further, a magnetic domain wall DW4 newly generated at the magnetic domain wall generator DWG moves to the bend part S11 through the straight-line part 61A, and is trapped at the bend part S11. As a result, the magnetization direction of the magnetization free layer 601 at the straight-line part 61A is reversed from the −X direction to the +X direction. However, the magnetization directions of the magnetization free layer 601 at the straight-line parts 61B, 61D, 62B, 62D, 63A to 63D, and 64A are unchanged from those in FIG. 4M.

In such a manner, in the rotation sensor 6, the rotation of the direction of the magnetic field Hm associated with the rotation of the magnet 2 causes the magnetic domain wall DW to move inside the magnetization free layer 601 along the winding direction. As the rotation of the direction of the magnetic field Hm associated with the rotation of the magnet 2 proceeds further, a larger number of magnetic domain walls DW are generated. Thus, in the rotation sensor 6, a state transition of the magnetization free layer 601 in the SV pattern 60, that is, a transition of the state of the magnetization free layer 601 including the number and positions of the magnetic domain walls DW in the magnetization free layer 601 and the magnetization directions of the magnetization free layer 601, occurs depending on the number of rotations and the rotation angle of the magnet 2. The SV pattern 60 exhibits a resistance value dependent on the state of the magnetization free layer 601.

For example, assume that the magnetization pinned layer 603 of the SV pattern 60 has a magnetization direction Pin set in a direction 45° rotated with respect to the +X direction toward the −Y direction, as indicated by a hollow arrow in each of FIGS. 4A to 4M. In such a case, a state where 90°<θ≤180° (see FIGS. 4D and 4E), in which the magnetic domain wall DW1 exists at the bend part S11, causes the straight-line part 61A to be higher in resistance than when in a state where 0°≤θ≤90° (see FIGS. 4A to 4C), in which no magnetic domain wall DW exists. Further, a state where 180°<θ≤270° (see FIGS. 4F and 4G), in which the magnetic domain wall DW1 has moved to the bend part S12, causes the straight-line part 61B to be higher in resistance than when in the state where 90°<θ≤180°.

Further, a state where 270°<θ≤360° (see FIGS. 4H and 4I), in which the magnetic domain walls DW1 and DW2 exist, causes each of the straight-line part 61A and the straight-line part 61C to be lower in resistance than when in the state where 180°<θ≤270°.

Further, a state where 360°<θ≤450° (see FIG. 4J), in which the magnetic domain walls DW1 and DW2 exist, causes each of the straight-line part 61B and the straight-line part 61D to be lower in resistance than when in the state where 270°<θ≤360°.

Further, a state where 450°<θ≤540° (see FIG. 4K), in which the magnetic domain walls DW1 to DW3 exist, causes each of the straight-line parts 61A and 62A to be higher in resistance and the straight-line part 61C to be lower in resistance than when in the state where 360°<θ≤450°.

Further, a state where 540°<θ≤630° (see FIG. 4L) causes each of the straight-line parts 61B, 61D, and 62B to be higher in resistance than when in the state where 450°<θ≤540°.

Further, a state where 630°<θ≤720° (see FIG. 4M) causes each of the straight-line parts 61A, 61C, 62A, and 62C to be lower in resistance than when in the state where 540°<θ≤630°.

In the rotation sensor 6, a sense current may be fed to each of the straight-line parts 61A to 61D, 62A to 62D, and 63A to 63D using the power supply terminal Vcc and the ground terminal GND, and a potential at each of the pads P11 to P13 and P21 to P23 may be measured. This makes it possible to detect electrical resistance of each of the straight-line parts 61A to 61D, 62A to 62D, and 63A to 63D. Such detection information allows the calculator 9 to calculate the number of rotations of the magnet 2.

### [Effects of Rotation Detection Apparatus 100]

In the present example embodiment, as described above, the temperature coefficient of residual magnetic flux density of the magnet 2 serving as a magnetic field generation source has an absolute value of 0.1%/° C. or less. This allows the magnet 2 to apply to the chip 4 a magnetic field Hm that exhibits a narrow intensity variation over a wider temperature range, such as a temperature range of −40° C. to +150° C. This allows movement of the magnetic domain wall DW in the magnetization free layer 601 of the SV pattern 60 associated with rotation of the magnet 2 to proceed with stability over a wider temperature range.

If, for example, the magnetic field to be applied to the SV pattern 60 is low in intensity, there is a concern that the movement of the magnetic domain wall DW can fail to sufficiently proceed. If the magnetic field to be applied to the SV pattern 60 is excessively high in intensity, a new magnetic domain wall DW rather than movement of an existing magnetic domain wall DW can be generated in the magnetization free layer 601, and can thereby cause the magnetization free layer 601 to be magnetically stabilized. This can give rise to a situation where an unintended resistance value is exhibited, leading to measurement error of the number of rotations. To avoid this, for example, intensity variation of the magnetic field may be suppressed to a range of about ±10%. In this regard, the rotation detection apparatus 100 of the present example embodiment uses the magnet 2 that is sufficiently small in terms of a change in magnetic field intensity caused by a change in the ambient temperature. In at least one embodiment, the magnet 2 has a temperature coefficient of residual magnetic flux density having an absolute value of 0.1%/° C. or less. This makes it possible for the rotation detection apparatus 100 to suppress intensity variation of the magnetic field, for application to the SV pattern 60, to the range of about ±10%. It is thus possible to resolve the issues described above, that is, insufficient proceeding of movement of the magnetic domain wall and unintended generation of a new magnetic domain wall. As a result, the rotation detection apparatus 100 of the present example embodiment is able to exhibit operation performance with higher stability, regardless of temperature environment in which the rotation detection apparatus 100 is to be installed.

### 2. APPLICATION EXAMPLE

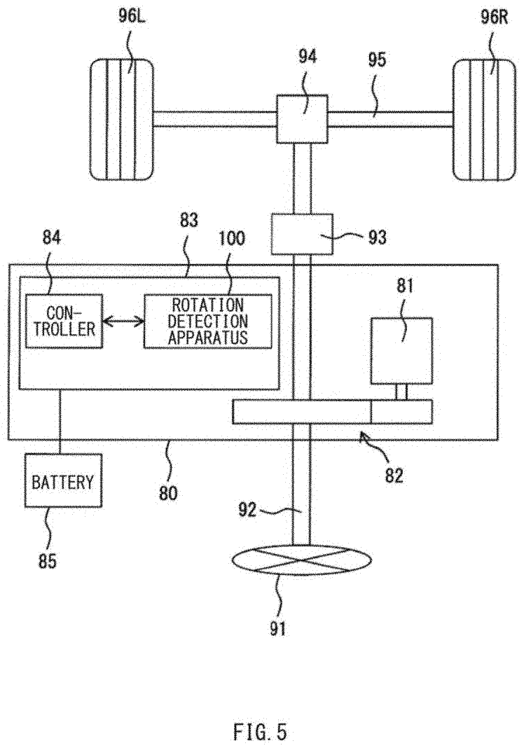

The rotation detection apparatus 100 described in the foregoing example embodiment is applicable to an electric power steering system installable in, for example, vehicles such as automobiles. FIG. 5 schematically illustrates some components of a vehicle. The vehicle illustrated in FIG. 5 may include an electric power steering system 80 including the rotation detection apparatus 100. Aside from the rotation detection apparatus 100, the vehicle illustrated in FIG. 5 may include a steering wheel 91, a shaft 92, a torque sensor 93, a pinion gear 94, a rack shaft 95, and wheels 96L and 96R.

The steering wheel 91 may be coupled to the shaft 92. The torque sensor 93 may be provided on the shaft 92 and may detect a steering torque to be applied to the steering wheel 91. The pinion gear 94 may be provided at an end of the shaft 92 and be engaged with the rack shaft 95. The pair of wheels 96L and 96R may be coupled to opposite ends of the rack shaft 95.

With such a configuration, the shaft 92 may rotate upon rotation of the steering wheel 91 by the driver. A rotary motion of the shaft 92 may be converted by the pinion gear 94 into a rectilinear motion of the rack shaft 95. The pair of wheels 96L and 96R may be steered to an angle corresponding to a displacement amount of the rack shaft 95.

The electric power steering system 80 may include, without limitation, a motor 81, a speed reduction gear 82, and an electric control unit 83. The motor 81 may output an assist torque that assists the driver in steering the steering wheel 91. The speed reduction gear 82 may decelerate rotation of the motor 81 and transmit the decelerated rotation to the shaft 92 or the rack shaft 95. The electric control unit 83 may be used to perform drive control on the motor 81.

The motor 81 may be driven by electric power supplied from a battery 85, and may rotate the speed reduction gear 82 forward and backward. The motor 81 may be a three-phase brushless motor, for example.

The electric control unit 83 may include the rotation detection apparatus 100 and a controller 84. The rotation detection apparatus 100 detects a rotation angle of the motor 81.

The vehicle illustrated in FIG. 5, which includes the electric power steering system 80 including the rotation detection apparatus 100 described in the foregoing example embodiment, resists being affected by a change in the ambient temperature, and is thus able to accurately detect the rotation angle of the motor 81 that outputs the assist torque assisting in steering the steering wheel 81. In some cases, during maintenance activities on the vehicle, steering can be brought into motion while no electric power is supplied to the rotation detection apparatus 100. However, with the electric power steering system 80, state transition by movement of a magnetic domain wall in the SV pattern 60 of the rotation detection apparatus 100 continues even under situations where power is lost. Upon resupply of the power, the number of rotations of the motor 81 is detectable as it is. It is thus possible for the motor 81 to output a correct assist torque even without performing any process, such as correction, after the maintenance activities.

### 3. MODIFICATION EXAMPLE

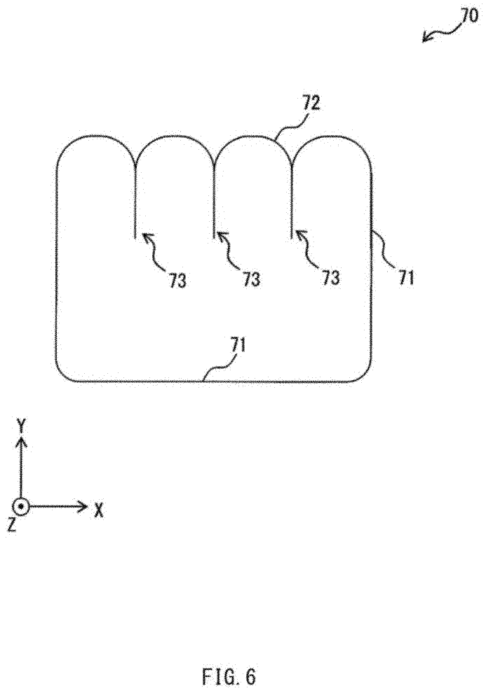

The technology has been described above with reference to the example embodiment. However, the technology is not limited thereto, and may be modified in a variety of ways. For example, although the SV pattern 60 that configures a spirally winding linear pattern is described as an example of the SV element in the foregoing example embodiment, the technology is not limited thereto. For example, FIG. 6 illustrates an SV pattern 70 according to a modification example. The SV pattern 70 may be a linear pattern including two or more U-shaped linear parts coupled to each other. The SV pattern 70 may include a straight-line part 71 extending straight along the XY plane, a curve part 72 extending in a curved shape, and a bend part 73 bending in the XY plane. The straight-line part 71, the curve part 72, and the bend part 73 may be coupled to each other. The SV pattern 70 having such a shape also allows movement of a magnetic domain wall to be generated by rotation of the magnet 2.

The technology encompasses any possible combination of some or all of the various embodiments and the modifications described herein and incorporated herein.

It is possible to achieve at least the following configurations from the foregoing embodiments and modification examples of the technology.
(1)

A magnetic field detection apparatus including:

a magnetic field generation source that is configured to change its orientation while generating a magnetic field, and has a temperature coefficient of residual magnetic flux density having an absolute value of 0.1 percent per degree centigrade or less; and

a spin valve element including a magnetic layer, the magnetic layer being configured to generate a movement of a magnetic domain wall in accordance with a change in direction of the magnetic field associated with a change in the orientation of the magnetic field generation source.
(2)

The magnetic field detection apparatus according to (1), in which the magnetic field generation source includes a permanent magnet.
(3)

The magnetic field detection apparatus according to (2), in which the permanent magnet includes aluminum, nickel, and cobalt as constituent materials.
(4)

The magnetic field detection apparatus according to (2), in which the permanent magnet includes samarium and cobalt as constituent materials.
(5)

The magnetic field detection apparatus according to any one of (1) to (4), in which

the magnetic layer has a magnetization in a direction along a first plane, and the spin valve element configures a linear pattern including: a straight-line part that extends straight along the first plane, a curve part that extends in a curved shape along the first plane, or both; and a bend part that bends in the first plane.
(6)

The magnetic field detection apparatus according to any one of (1) to (4), in which

the magnetic layer has a magnetization along a first plane, and

the spin valve element configures a linear pattern that winds spirally in a plane parallel to the first plane, the linear pattern including: a first straight-line part and a second straight-line part that each extend straight along the first plane; and a bend part that couples the first straight-line part and the second straight-line part to each other.
(7)

A rotation detection apparatus including:

a magnetic field generation source that is rotatable while generating a magnetic field, and has a temperature coefficient of residual magnetic flux density having an absolute value of 0.1 percent per degree centigrade or less;

a spin valve element including a magnetic layer, the magnetic layer being configured to generate a movement of a magnetic domain wall in accordance with a change in direction of the magnetic field associated with a rotation of the magnetic field generation source; and

a calculator configured to detect a change in resistance of the spin valve element caused by the movement of the magnetic domain wall and to calculate the number of rotations or a rotation angle of the magnetic field generation source.
(8)

An electric power steering system including

a motor configured to output a torque that assists a driver in steering, and

a rotation detection apparatus configured to detect a rotation angle of the motor,

the rotation detection apparatus including:
a magnetic field generation source that is rotatable while generating a magnetic field, and has a temperature coefficient of residual magnetic flux density having an absolute value of 0.1 percent per degree centigrade or less;
a spin valve element including a magnetic layer, the magnetic layer being configured to generate a movement of a magnetic domain wall in accordance with a change in direction of the magnetic field associated with a rotation of the magnetic field generation source; and
a calculator configured to detect a change in resistance of the spin valve element caused by the movement of the magnetic domain wall and to calculate the number of rotations or a rotation angle of the magnetic field generation source. The magnetic field detection apparatus, the rotation detection apparatus, and the electric power steering system according to at least one embodiment of the technology each exhibit stable operation performance over a wider temperature range.

Although the technology has been described hereinabove in terms of the example embodiment and modification examples, it is not limited thereto. It should be appreciated that variations may be made in the described example embodiment and modification examples by those skilled in the art without departing from the scope of the disclosure as defined by the following claims. The limitations in the claims are to be interpreted broadly based on the language employed in the claims and not limited to examples described in this specification or during the prosecution of the application, and the examples are to be construed as non-exclusive. The use of the terms first, second, etc. do not denote any order or importance, but rather the terms first, second, etc. are used to distinguish one element from another. The term “substantially” and its variants are defined as being largely but not necessarily wholly what is specified as understood by one of ordinary skill in the art. The term “disposed on/provided on/formed on” and its variants as used herein refer to elements disposed directly in contact with each other or indirectly by having intervening structures therebetween. Moreover, no element or component in this disclosure is intended to be dedicated to the public regardless of whether the element or component is explicitly recited in the following claims.

What is claimed is:

1. A magnetic field detection apparatus comprising:
a magnetic field generation source that is configured to change its orientation while generating a magnetic field, and has a temperature coefficient of residual magnetic flux density having an absolute value of 0.1 percent per degree centigrade or less; and
a spin valve element including a magnetic layer, the magnetic layer being configured to generate a movement of a magnetic domain wall in accordance with a change in direction of the magnetic field associated with a change in the orientation of the magnetic field generation source.

2. The magnetic field detection apparatus according to claim 1, wherein the magnetic field generation source comprises a permanent magnet.

3. The magnetic field detection apparatus according to claim 2, wherein the permanent magnet includes aluminum, nickel, and cobalt as constituent materials.

4. The magnetic field detection apparatus according to claim 2, wherein the permanent magnet includes samarium and cobalt as constituent materials.

5. The magnetic field detection apparatus according to claim 1, wherein
the magnetic layer has a magnetization in a direction along a first plane, and
the spin valve element configures a linear pattern including: a straight-line part that extends straight along the first plane, a curve part that extends in a curved shape along the first plane, or both; and a bend part that bends in the first plane.

6. The magnetic field detection apparatus according to claim 1, wherein
the magnetic layer has a magnetization along a first plane, and
the spin valve element configures a linear pattern that winds spirally in a plane parallel to the first plane, the linear pattern including: a first straight-line part and a second straight-line part that each extend straight along the first plane; and a bend part that couples the first straight-line part and the second straight-line part to each other.

7. A rotation detection apparatus comprising:
a magnetic field generation source that is rotatable while generating a magnetic field, and has a temperature coefficient of residual magnetic flux density having an absolute value of 0.1 percent per degree centigrade or less;
a spin valve element including a magnetic layer, the magnetic layer being configured to generate a movement of a magnetic domain wall in accordance with a change in direction of the magnetic field associated with a rotation of the magnetic field generation source; and
a calculator configured to detect a change in resistance of the spin valve element caused by the movement of the magnetic domain wall and to calculate the number of rotations or a rotation angle of the magnetic field generation source.

8. An electric power steering system including
a motor configured to output a torque that assists a driver in steering, and
a rotation detection apparatus configured to detect a rotation angle of the motor,
the rotation detection apparatus comprising:
a magnetic field generation source that is rotatable while generating a magnetic field, and has a temperature coefficient of residual magnetic flux density having an absolute value of 0.1 percent per degree centigrade or less;
a spin valve element including a magnetic layer, the magnetic layer being configured to generate a movement of a magnetic domain wall in accordance with a change in direction of the magnetic field associated with a rotation of the magnetic field generation source; and
a calculator configured to detect a change in resistance of the spin valve element caused by the movement of the magnetic domain wall and to calculate the number of rotations or a rotation angle of the magnetic field generation source.
